(19) United States
(12) Patent Application Publication
(10) Pub. No.: US 2025/0264554 A1
(43) Pub. Date: Aug. 21, 2025

(54) CLOSED LOOP MAGNETIC FIELD SENSOR WITH CURRENT CONTROL

(71) Applicant: Allegro MicroSystems, LLC, Manchester, NH (US)

(72) Inventor: Pablo Castro Lisboa, Montevideo (UY)

(73) Assignee: Allegro MicroSystems, LLC, Manchester, NH (US)

(21) Appl. No.: 18/442,537

(22) Filed: Feb. 15, 2024

(51) Int. Cl. G01R 33/00; G01R 15/20; G01R 33/07; G01R 33/09

(52) U.S. Cl. CPC G01R 33/0041; G01R 15/20; G01R 33/07; G01R 33/09

(57) ABSTRACT

Method and apparatus for a closed loop CAPS magnetic field sensor having an emitter coil current that corresponds to a distance from a target. An emitter coil drive circuit outputs an emitter current to an emitter coil for generating an emitter field and a reference coil drive circuit outputs a reference current to a reference coil for generating a reference field. The combined fields generate an applied field and a magnetic field sensing element generates an electric signal. The sensor has a closed loop configuration with a feedback path that includes the emitter coil drive circuit and the emitter coil and is configured to modify an amplitude of the emitter current signal based on a distance from the target to the magnetic field sensing element.

### BACKGROUND

Magnetic field sensors utilize magnetic field sensing elements to detect one or more magnetic fields. Magnetic field sensors are often used to detect a ferromagnetic or conductive target and may generally act to detect motion or position of the target. Such sensors are found in many technology areas including robotics, automotive, manufacturing and so forth. For example, a magnetic field sensor may be used to detect when a vehicle wheel locks up (stops rotating), which triggered the vehicle's control processor to engage an anti-lock braking system. Magnetic field sensors may also detect distance to an object. As examples, magnetic field sensors may be used to detect the position of a hydraulic piston or angular position of a steering column.

A magnetic field sensing element may be a single element or, alternatively, may include two or more magnetic field sensing elements arranged in various configurations, e.g., a half-bridge or full-bridge (Wheatstone) configuration. Depending on the device type and/or other application requirements, a magnetic field sensing element may include, e.g., a type IV semiconductor material such as Silicon (Si) or Germanium (Ge), or a type III-V semiconductor material like Gallium-Arsenide (GaAs) or an Indium compound, e.g., Indium-Antimonide (InSb).

Hall effect elements are one type of magnetic field sensing elements that generate a variable voltage in response to changes in an applied or sensed magnetic field. Magnetoresistance elements are another type of magnetic field sensing element that has a variable resistance that changes in response to changes in an applied or sensed magnetic field. There are different types of magnetoresistance elements, for example, semiconductor magnetoresistance elements such as ones including Indium Antimonide (InSb), anisotropic magnetoresistance (AMR) elements, giant magnetoresistance (GMR) elements, and tunneling magnetoresistance (TMR) elements, which are also referred to as magnetic tunnel junction (MTJ) elements. Some magnetoresistance elements, e.g., GMR and TMR elements, may have a limited linear output range in which a change in sensed magnetic field intensity is linear with respect to a corresponding change in the resistance of the elements.

### SUMMARY

Example embodiments of the disclosure provide methods and apparatus for a coil activated position sensor (CAPS) having current consumption control. In example embodiments, a sensor includes a reference coil and an emitter coil driver, which are in the feedback path of the closed loop sensor. With this arrangement, air gap distance, for example, can correspond to emitter coil current level used for sensing targets.

In one aspect, a magnetic field sensor comprises: an emitter coil drive circuit for outputting an emitter current to an emitter coil for generating an emitter field; a reference coil drive circuit for outputting a reference current to a reference coil for generating a reference field; a combiner to combine a reflected field generated by a target in response to the emitter field and the reference field and output an applied field; a magnetic field sensing element to receive the applied field and generate an electric signal; an amplifier to amplify the electric signal, wherein an output of the amplifier is coupled to the emitter coil drive circuit; a transconductance module to generate an output current from the electric signal; wherein the sensor comprises a closed loop configuration with a feedback path that includes the emitter coil drive circuit and the emitter coil and is configured to modify an amplitude of the emitter current signal based on a distance from the target to the magnetic field sensing element.

A sensor can further comprise one or more of the following features: the applied field comprises a signal at carrier frequency, the output signal from the magnetic field sensing element is demodulated to a baseband frequency and input to the amplifier, the distance d is determined as:

$$d = {K}_{EC}^{- 1} ( \frac{{I}_{R C} \cdot {K}_{R C}}{{I}_{O} \cdot K} ) ,$$

where Io is the output current from the transconductance module, I_{RC} is the reference current,

| | | |
|---|---|---|
| K_{EC}(d) | [G/A] | Ratio between the emitting coil current IEC and the |
| | | reflected magnetic field BR |
| K_{FC}, K_{RC} | [G/A] | Feedback and reference coils sensitivity |
| K | [A/A] | Transconductances ratio |

the emitter current is determined as:

$${I}_{EC} = {I}_{R C} \cdot {K}_{R C} . \frac{1}{{K}_{EC} ( d )} ,$$

where I_{RC} is the reference current, and

| | | |
|---|---|---|
| K_{EC}(d) | [G/A] | Ratio between the emitting coil current I_{EC} and |
| | | the reflected magnetic field BR |
| K_{FC}, K_{RC} | [G/A] | Feedback and reference coils sensitivity |

the magnetic field sensing element comprises a magnetoresistance (MR) element, and/or the magnetic field sensing element comprises a Hall element.

In another aspect, a method comprises outputting an emitter current to an emitter coil for generating an emitter field; outputting a reference current to a reference coil for generating a reference field; combining a reflected field generated by a target in response to the emitter field and the reference field and output an applied field; receiving the applied field and generating an electric signal by a magnetic field sensing element in a magnetic field sensor; amplifying the electric signal with an amplifier, wherein an output of the amplifier is coupled to an emitter coil drive circuit for generating the emitter current; and generating an output current from the electric signal, wherein the sensor comprises a closed loop configuration with a feedback path that includes the emitter coil drive circuit and the emitter coil and is configured to modify an amplitude of the emitter current signal based on a distance from the target to the magnetic field sensing element.

A method can further include one or more of the following features: the applied field comprises a signal at carrier frequency, the output signal from the magnetic field sensing element is demodulated to a baseband frequency and input to the amplifier, the distance d is determined as:

$$d = {K}_{EC}^{- 1} ( \frac{{I}_{R C} \cdot {K}_{R C}}{{I}_{O} \cdot K} ) ,$$

where Io is the output current from the transconductance module, I_{RC} is the reference current,

| | | |
|---|---|---|
| K_{EC}(d) | [G/A] | Ratio between the emitting coil current IEC and |
| | | the reflected magnetic field BR |
| K_{FC}, K_{RC} | [G/A] | Feedback and reference coils sensitivity |
| K | [A/A] | Transconductances ratio |

the emitter current is determined as:

$${I}_{EC} = {I}_{R C} \cdot {K}_{R C} \cdot \frac{1}{{K}_{EC} ( d )} ,$$

where I_{RC} is the reference current, and

| | | |
|---|---|---|
| K_{EC}(d) | [G/A] | Ratio between the emitting coil current I_{EC} and |
| | | the reflected magnetic field BR |
| K_{FC}, K_{RC} | [G/A] | Feedback and reference coils sensitivity |

the magnetic field sensing element comprises a magnetoresistance (MR) element, and/or the magnetic field sensing element comprises a Hall element.

In a further aspect, a magnetic field sensor comprises: an emitter coil drive circuit for outputting an emitter current to an emitter coil for generating an emitter field; a reference coil drive circuit for outputting a reference current to a reference coil for generating a reference field; a combiner to combine a reflected field generated by a target in response to the emitter field and the reference field and output an applied field; a magnetic field sensing element to receive the applied field and generate an electric signal; an amplifier to amplify the electric signal, wherein an output of the amplifier is coupled to the emitter coil drive circuit; a transconductance module to generate an output current from the electric signal; and a means for providing a closed loop feedback.

### BRIEF DESCRIPTION OF THE DRAWINGS

The foregoing features of this disclosure, as well as the disclosure itself, may be more fully understood from the following description of the drawings in which:

FIG. 1 is a block diagram of an example magnetic field sensor having for detecting an applied magnetic field;

FIG. 2 shows an example implementation of the magnetic field sensor of FIG. 1;

FIG. 3 is a schematic representation of an open loop magnetic field coil activated position sensor (CAPS);

FIG. 3A shows an example distance d from a target to a sensing element on a die;

FIG. 4 is a schematic representation of a closed loop magnetic field coil activated position sensor (CAPS) in which the target and the reflected magnetic field BR are not part of the loop (BR is the input);

FIG. 5 is a schematic representation of a closed loop magnetic field coil activated position sensor (CAPS) having emitter coil current that corresponds to air gap distance in which the target and the reflected magnetic field are part of the feedback loop;

FIG. 6 is a block diagram of a closed loop sensor having feedback shown as a generalization of the sensor of FIG. 5;

FIG. 7 is a flow diagram showing an example sequence of steps for controlling emitter coil current based on distance in a closed loop magnetic field coil activated position sensor (CAPS); and

FIG. 8 is a schematic representation of an example computer that can perform at least a portion of the processing described herein.

### DETAILED DESCRIPTION

Some introductory information is provided prior to describing example embodiments of the disclosure. A sensed magnetic field, referred to herein alternatively as the applied magnetic field, can be from an external magnetic field source or a reflected field and can be amplified and fed back to the magnetic field sensing elements, e.g., MR elements, by a feedback coil such that the magnetic field sensing elements operate in a linear range. The feedback configuration can be a negative feedback configuration, in exemplary embodiments.

As used herein, the term “magnetic field sensor” is used to describe a circuit that uses one or more magnetic field sensing elements, generally in combination with other circuits. Magnetic field sensors are used in a variety of applications, including, but not limited to, angle sensors that sense an angle of a direction of a magnetic field, current sensors that sense a magnetic field generated by a current carried by a current-carrying conductor, magnetic switches that sense the proximity of a ferromagnetic object, rotation detectors that sense passing ferromagnetic articles, for example, magnetic domains of a ring magnet or a ferromagnetic target (e.g., gear teeth) where the magnetic field sensor is used in combination with a back-biased or other magnet, and magnetic field sensors that sense a magnetic field density of a magnetic field.

As used herein, the term “target” is used to describe an object or portion of an object to be sensed or detected by a magnetic field sensor or a magnetic field sensing element such as a magnetoresistance element. The target may include a conductive material that allows for eddy currents to flow within the target.

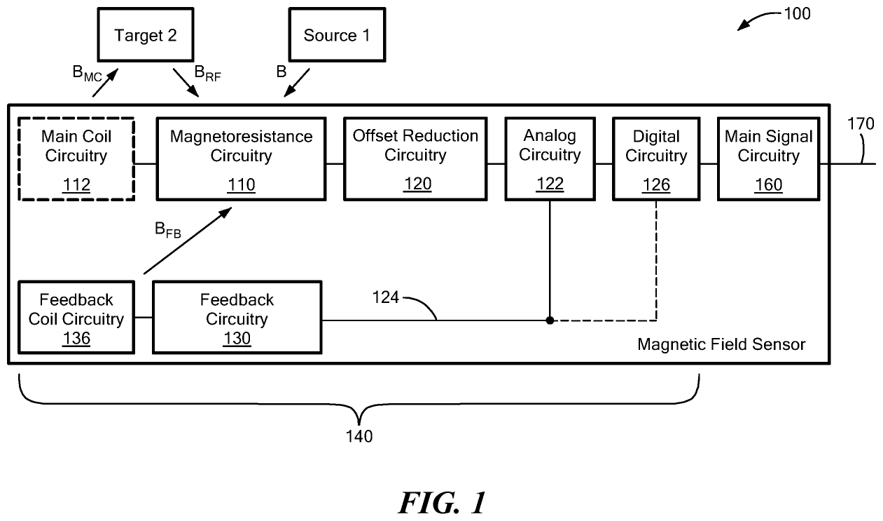

FIG. 1 is a block diagram of an example of a magnetic field coil activated position sensor (CAPS) 100. Magnetic field sensor 100 includes magnetoresistance circuitry 110 that is part of a magnetic closed loop (a.k.a., feedback loop) 140 including feedback circuitry 130 and feedback coil circuitry 136 that generates a feedback magnetic field (B_{FB}).

The magnetoresistance circuitry 110 is configured to sense or detect one or more magnetic fields, including a residual magnetic field (a.k.a., a resultant or error magnetic field) resulting from a combination of an external applied (B) or reflected (B_{RF}) magnetic field, which may be modulated at a first frequency (f₁), and the feedback magnetic field (B_{FB}). Magnetoresistance elements 110 can have relatively poor signal to offset ratios and, in fact, can have offset levels that are much larger than the maximum signal to be sensed.

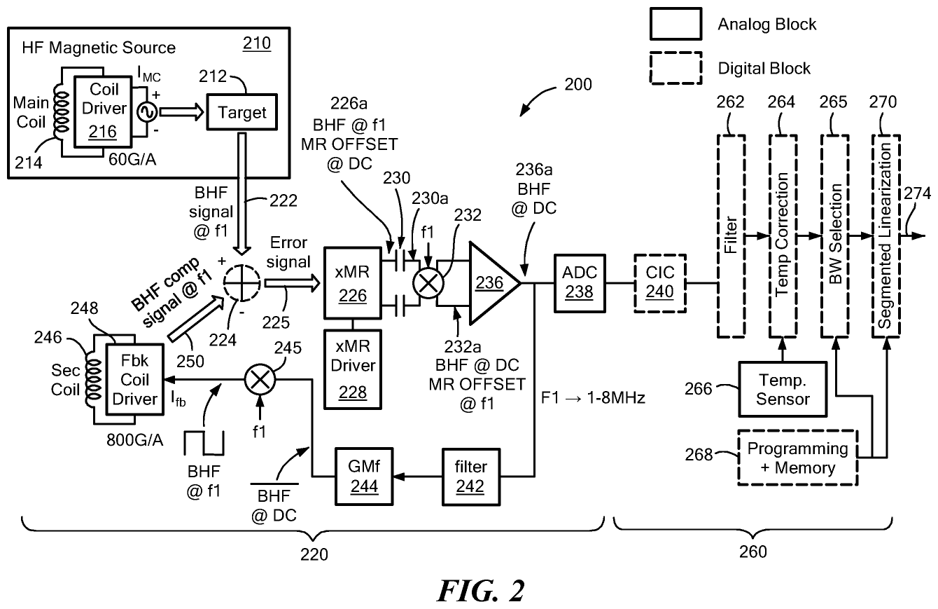

Offset reduction circuitry 120 is responsive to the magnetoresistance circuitry 110 and is configured to reduce undesired baseband components such as components attributable to the magnetoresistance circuitry 110. Example offset reduction circuitry 120 can take the form of AC coupling circuitry as shown and described in connection with FIG. 2. The offset reduction circuitry 110 prevents undesired DC signal components from creating high frequency ripple, which would undesirably generate excessive power consumption due to current through the feedback coil and would increase the dynamic residual offset and thus, reduce the dynamic range of the system. Thus, stated differently, the offset reduction circuitry 120 prevents such ripple generation, thus optimizing power consumption, minimizing residual offset and maximizing output dynamic range (i.e., ensuring that the dynamic range of the system is available for processing the useful signal).

Sensor 100 can also include analog circuitry 122, e.g., one or more amplifiers, and digital circuitry 126, e.g., one or more filters, which can be used to process and/or condition the output signals of the offset reduction circuitry 120 to generate a feedback signal 124. The closed loop 140 is configured to use the feedback signal 124 to generate the feedback magnetic field (B_{FB}) and supply the feedback magnetic field (B_{FB}) to the magnetoresistance circuitry 110. The feedback loop 140 can be an analog closed loop as illustrated by the solid line feedback signal 124 from analog circuitry 122 or a digital closed loop as illustrated by the dotted line feedback signal 124 from the digital circuitry 126. It will be appreciated by those of ordinary skill in the art that, in the case of a digital feedback circuit, a DAC is provided (as may be part of the feedback circuitry 130) in order to convert the digital signal back to the analog domain in order to drive the coil.

Main signal circuitry 160 can process a main signal from the magnetoresistance circuitry 110, e.g., for measuring a position of a source 1 or target 2, in order to generate a sensor output signal 170 that can be indicative of the position and/or motion of the source 1 or target 2.

The applied magnetic field can be a magnetic field (B) generated by a magnetic field source 1 and/or a reflected magnetic field (B_{RF}) reflected from a target 2, e.g., a conductive target. In example embodiments, a target 2 may include, but is not limited to, a portion of a moving metal machine component such as a gear tooth, a camshaft lobe, a magnetic domain on a rotating shaft, or a magnetic domain on a rotating/moving element, etc. For embodiments sensing a reflected magnetic field (B_{RF}) reflected from a target 2, the sensed magnetic field can result from a main coil magnetic field (BMC) that is generated by a main coil as part of main coil circuitry 112 that is reflected from the target 2 as the reflected magnetic field (B_{RF}), with the reflected magnetic field allowing measurement of a parameter associated with the target 2.

FIG. 2 shows an example of a closed loop magnetic field sensor 200 for detecting an applied magnetic field (BHF) 222. The magnetic field sensor 200 includes a magnetic closed loop 220 including magnetoresistance circuitry 226, feedback circuitry 244, and a feedback coil 246 configured to generate a feedback magnetic field 250. The magnetoresistance circuitry 226 is configured to receive or detect a residual magnetic field 225 resulting from a combination of applied magnetic field 222 and feedback magnetic field 250 and produce a corresponding electrical output signal 226a, e.g., as a differential output voltage signal. Magnetoresistance circuitry 226 can be driven by a magnetoresistance driver 228. In example embodiments, the magnetoresistance circuitry 226 can include multiple magnetoresistance elements, e.g., four elements, in a bridge configuration.

Magnetic field 222 can be generated by a magnetic source 210 including a target 212 and a main coil 214 and driver 216. In this configuration, the applied field 222 can be a reflected magnetic field (B_{RF}) reflected from a conductive target 212. In example embodiments, target 212 may include, but is not limited to, a portion of a moving metal machine component such as a gear tooth, a camshaft lobe, a magnetic domain on a rotating shaft, or a magnetic domain on a rotating/moving element, etc. For embodiments sensing a reflected magnetic field (B_{RF}) reflected from a target 212, the sensed magnetic field can result from a main coil magnetic field (BMC) that is generated by the main coil 214 driven by driver 216 and that is then directed to and reflected from the target 212 as the reflected magnetic field (B_{RF}), with the reflected magnetic field allowing measurement of a position of the target. In such embodiments, the applied magnetic field 222 can include a signal having a relatively high frequency f₁ that is indicative of a useful signal of interest for processing by a main signal path 260 to generate an output signal 274 of the sensor 200.

In example embodiments, the feedback magnetic field 250 can be combined with the applied magnetic field 222 in a negative feedback configuration (as indicated by negative sign at 224) to form a residual magnetic field 225 that is near zero, e.g., in the linear operational range of the magnetoresistance circuitry 226. For example, by having opposite polarities, the applied magnetic field 222 and the feedback magnetic field 250 may sum to near zero. In alternate embodiments, the feedback magnetic field 250 can be combined with the applied magnetic field 222 in a negative feedback configuration with a large open loop gain, e.g., such that the residual magnetic field 225 is near zero. It is understood that this feedback is always negative.

Applied magnetic field 222 and feedback magnetic field 250 are indicated as being combined by sum unit 224, however an electronic sum unit 224 is not necessary for combination of the magnetic fields 222, 250 as they may be combined (e.g., be superposed) in any medium or in free space. For example, placement and/or geometry of sensing elements of magnetoresistance circuitry 226 with respect to the magnetic source 210 and feedback coil 246 can result in generation of the residual magnetic field 225 as the difference between the applied magnetic field 222 and the feedback magnetic field 250. As shown, when the fields are combined, feedback magnetic field 250 can be subtracted from applied magnetic field 222 to result in residual magnetic field 225.

The feedback magnetic field 250 generated by the feedback coil 246 can accordingly be used, in example embodiments, to reduce or attenuate the residual magnetic field such that the magnetoresistance circuitry 226 is operational in a linear region of the transfer function curve of the magnetoresistance elements. In example embodiments, the feedback magnetic field 250 can include a scaled replica of the applied magnetic field 222. Use of the feedback magnetic field 250 can accordingly allow the magnetoresistance circuitry 226 to be used in a linear range of operation and mitigate negative effects arising from undesirable signal components, for example, stray magnetic fields or by temperature or mechanical stresses that may be included in the applied magnetic field 222. The closed magnetic loop 220 can include one or more amplifiers 236 to provide a desired loop gain, without relying on the sensitivity or gain of the magnetoresistance circuitry 226.

Output signal 226a of the MR elements 226 can contain high frequency components of interest (i.e., components corresponding to the useful signal to be sensed) at the first frequency f₁ and undesirable offset components at baseband as may be attributable to offset of the MR elements 226.

Offset reduction circuitry 230 configured to reduce the undesired baseband components includes series coupled capacitors, as shown. Capacitors 230 block the undesired baseband components due to offset to thereby generate a signal 230a having little or no undesired baseband components.

A modulator 232 is coupled to the capacitors 230 and is configured to shift the frequency of the received signal so that an output signal 232a of the modulator 232 includes a baseband portion indicative of a useful signal of interest (referred to herein as a main signal portion) and any undesirable offset component at frequency f₁.

Amplifier 236 is coupled to receive the modulator output signal 232a and to amplify the signal in order to generate a superimposed signal 236a containing a main signal portion of interest at DC and an offset reduced signal portion (i.e., any remaining undesirable offset components) at frequency f₁. The superimposed signal 236a can be provided to feedback circuitry to drive feedback coil 246 and generate the feedback magnetic field 250. For example, the superimposed signal 236a can be filtered by a filter 242 and converted from a voltage to a current by a transconductance amplifier 244. Ideally, any undesirable offset components are significantly attenuated by the capacitors 230 and so that the superimposed signal 236a at the output of amplifier 236 contains only the main signal of interest at baseband and little to no high frequency components representing offset components; however, in the event that such high frequency undesirable offset components remain in signal 236a, they can be removed by low pass filter 242 for example.

A second modulator 245 can be coupled to receive the output current signal from the transconductance amplifier 244 and generate a feedback signal Ifb for coupling to the coil driver 248. Feedback coil driver 248 can generate the drive signal for the feedback coil 246 to generate the feedback magnetic field 250 based on the feedback signal.

It will be appreciated by those of ordinary skill in the art that although the magnetic feedback loop 220 shown in the embodiment of FIG. 2 is analog (i.e., the superimposed signal is analog and conversion to the digital domain is performed by ADC 238 for digital processing by the main signal path 260), in other embodiments the closed loop 220 can include digital signals and components (e.g., as illustrated by the dotted line in FIG. 1).

The superimposed signal 236a can also be provided to main signal path 260 for extracting the main signal component and producing an output signal 274 of the magnetic field sensor 200. The signal 236a may be provided to an analog-to-digital converter 238 to convert the signal 236a from an analog signal to a digital signal. One or more filters, e.g., cascaded integrator-comb (CIC) filter 240 and/or digital filter 262, may be included for filtering, as low pass filters to remove high frequency components.

Main signal path 260 can include a temperature correction circuit 264, a temperature sensor 266, a programming and memory circuit 268, a bandwidth selection block 265, and a segmented linearization block 270, providing main signal output 274. Temperature correction block 264 may scale the output voltage signal according to temperature, e.g., a temperature measured by the temperature sensor 266. Main signal path 260 can provide main signal output 274, which in example embodiments may be indicative of an angle or position or other parameter such as speed associated with the target 212.

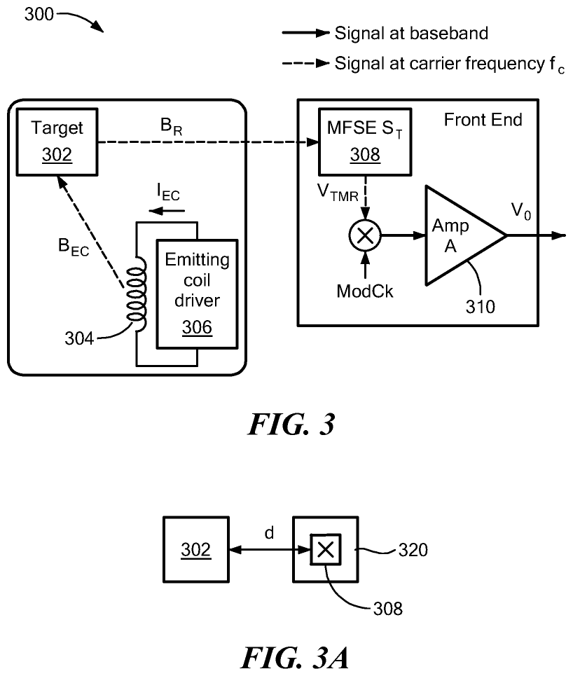

FIG. 3 shows a high level schematic representation of an open loop CAPS sensor 300 for sensing a target 302 distance d using a field B_{EC} emitted by an emitting coil 304 controlled by a coil driver 306 that outputs a coil current I_{EC}. A field BR reflected by the target 302 is sensed by magnetic field sensing element(s) (MFSE) 308 having a given sensitivity S_{T}. An output voltage V_{TMR} is combined with a clock signal ModCk and input to an amplifier 310 which generates an output voltage Vo that corresponds to the strength of field B_{R}. In embodiments, as shown in FIG. 3A, distance d can be defined as the distance from a surface of the target 302 closest to the MFSE 308 on a die 320 that can provide circuitry in addition to MFSE. In the illustrated embodiment, circuitry, such as amplifier 310 and MFSE 308, are shown in one section and magnetics, such as emitting coil 304 and target 302, are shown in a different section for ease of understanding. In example embodiments, a sensor IC package will be positioned in relation to the target.

The signal of interest (at base band) is modulated at the carrier frequency f_{c} to generate eddy currents in the target 302. The relationship of the different system parameters can be represented in Equation (1) as follows:

$${V}_{O} = {I}_{EC} \cdot {K}_{EC} ( d ) \cdot {S}_{T} \cdot A \qquad ( 1 )$$

$$where {K}_{EC} = {B}_{R} / {I}_{EC}$$

Example parameters used in one or more of the equations used herein are set forth in the below table.

| Parameter | Magnitude | Description |
|---|---|---|
| B_{R} [1] | [G] | Reflected magnetic field |
| B_{EC}[2] | [G] | Emitted by the emitting coil magnetic field |
| B_{FC}[1] | [G] | Feedback magnetic field |
| Bₑ[1] | [G] | Error magnetic field for the closed loop |
| | | architectures. |
| B_{REF}[¹] | [G] | Reference magnetic field for the proposed |
| | | architecture |
| B_{N}[1] | [G] | Input equivalent noise |
| I_{EC} | [A] | Emitting coil current |
| K_{EC}(d) | [G/A] | Ratio between the emitting coil current IEC and |
| | | the reflected magnetic field BR |
| S_{T} | [V/G] | MFSE sensitivity |
| A | [V/V] | Amplifier gain |
| I_{ΣΔ}, | [A] | Input to sigma delta modulator current |
| V_{O} | [V] | Amplifier output voltage |
| K_{FC}, K_{RC} | [G/A] | Feedback and reference coils sensitivity |
| K | [A/A] | Transconductances ratio |
| ModCk | — | Clock used to modulate/demodulate the signal |
| | | of interest |

(1) - These magnetic fields are located at the MFSE.
(2) - This magnetic field is located at the emitting coil.

It should be noted that the sensitivity of the magnetic field sensing element S_{T} can have variations due different effects.

In other embodiments, a second MSFE, or more, is used to normalize the output and make Equation 1 independent on the sensitivity S_{T}. However, variations due to different effects in this parameter can still have a significant impact in the measure. For example, TMR elements have relatively large amounts of variation in resistance values.

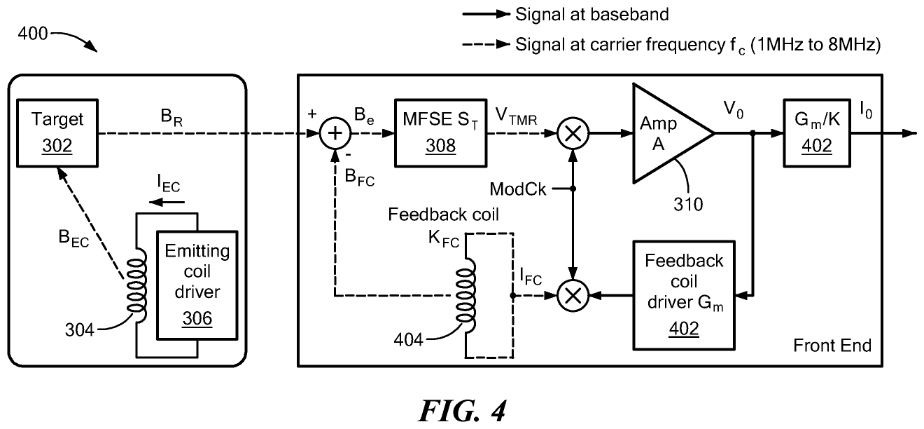

FIG. 4 shows an example sensor 400 that addresses such effects in the variations of MFSE 308 sensitivity and implements a closed loop architecture with the MFSE are in the forward path, where like reference numbers indicated like elements in FIG. 3. With a large enough open loop gain, the sensor sensitivity becomes independent on S_{T}. To close the loop, an auxiliary coil (feedback coil) 404 generates an equal in amplitude field B_{FC} but opposite in direction field to reflected magnetic field B_{R}. Thus, the loop is closed at the magnetic field level. A feedback coil driver 402 drives the feedback coil 404 with a drive signal combined with clock signal ModCk. The feedback coil field B_{FC} is summed with the reflected magnetic field B_{R} the output Be of which is sensed by the sensing element 308. As can be seen, the feedback coil driver 402 and the feedback coil 404 are in the feedback path.

Equation 2 below shows that the system sensitivity has no dependence on S_{T}. The output current Io corresponds to target distance, and more particularly, the emitting coil current I_{EC} and the ratio between the emitting coil current I_{EC} and the reflected magnetic field B_{R}. It should be noted that feedback coil sensitivity K_{FC} has no variation issues because it only depends on the geometry.

$${I}_{O} = {I}_{EC} \cdot {K}_{EC} ( d ) \cdot \frac{1}{{K}_{FC} \cdot K} {\overbrace{= >}}^{If} ( {S}_{T} \cdot A \cdot {G}_{m} \cdot {K}_{FC} >> 1 ) \qquad ( 2 )$$

It is understood that (S_{T}. A. Gₘ. K_{FC}) refers to the open loop gain. The above expression is accurate if the open loop gain is much greater than 1.

Another parameter for sensor performance is the signal to noise ratio (SNR). Equation 3 shows parameters for the system shown in FIG. 4. In this equation B_{N} is the whole system input equivalent noise. As K_{EC} (d) depends on target distance, the SNR depends on it too. SNR decreases as distance increases.

$$S N R = \frac{{B}_{REF}}{{B}_{N}} = \frac{{K}_{EC} ( d ) \cdot {I}_{EC}}{{B}_{N}} \qquad ( 3 )$$

As defined above B_{N} is the input equivalent noise.

One of the issues that conventional sensors configurations present is that the amplitude of the emitting coil current I_{EC} delivered to the emitting coil is constant. When the distance d between the sensor die and the target is large, a large current amplitude is necessary. However, when the distance is short, the current amplitude can be smaller. For example, an emitter coil current may be a 1 MHz square wave at 8 mA, which may generate a relatively large reflected field B_{R} when the target is closed to the sensor IC package.

In example embodiments of the disclosure, the dynamic adaptability of a closed loop sensor configuration is used to set an emitting coil current amplitude that corresponds to the distance between the die and the target.

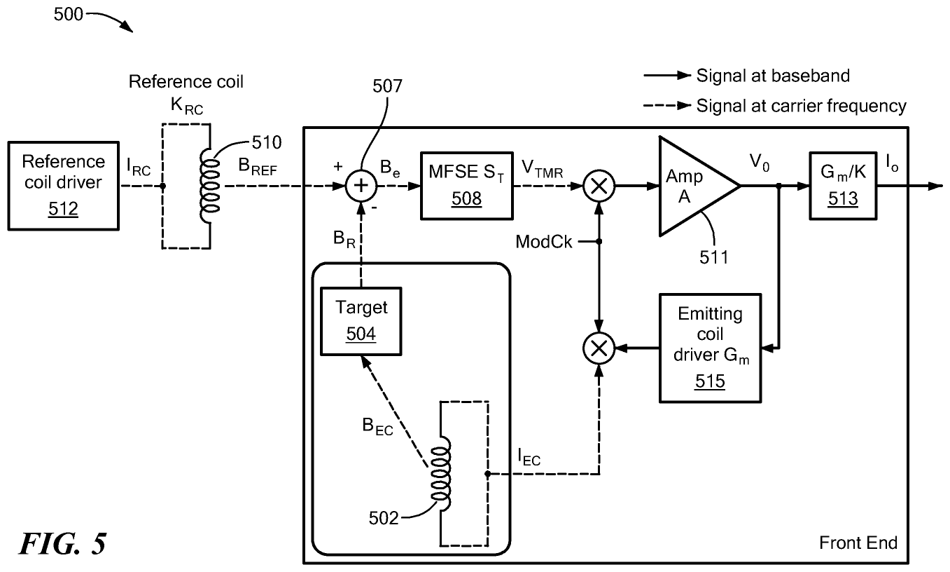

FIG. 5 shows an example closed loop sensor 500 having an emitting coil 502 and a target 504 that are part of the feedback loop. To be able to set the operating point of the loop, a reference magnetic field B_{REF} is generated by a reference coil 510 driven by a reference coil driver circuit 512 which generates a reference coil current I_{RC}. This reference can be injected in the loop using a coil like the one used to implement the feedback loop in FIG. 4 but now used as the input to the system. The reference field B_{REF} and the reflected field B_{R} are summed 507 to generate an output Be that can be applied to the sensing element 508. The voltage output V_{TMR} from the sensing element(s) 508 and be combined with clock signal ModCk and input to amplifier 511 to generate the output voltage Vo. A transconductance circuit 513 receives the output voltage Vo and generates an output current Io based on transconductance Gₘ and transconductances ratio K. The output voltage Vo is feed back to the emitter coil driver 515, which has transconductance Gₘ. The emitter coil driver 515 drives the emitter coil 502 with emitter coil current I_{EC} to generate a reflected field B_{R} from the target 504.

In the illustrated embodiment, the target is external to the IC package. It is understood that in other embodiments some components, such as a coil, can be external to the IC package.

In this way, the applied magnetic field (BE) to the MFSE 508 can be considered as very small, because of the large open loop gain. Thus, the MFSE 508 works without applied magnetic field.

Equation 4 shows the relationship between the output current Io and the distance d to be measured.

$${I}_{o} = {I}_{RC} \cdot {K}_{RC} \cdot \frac{1}{{K}_{EC} ( d ) \cdot K} {\overbrace{= >}}^{If} ( {S}_{T} \cdot A \cdot {G}_{m} \cdot {K}_{EC} ( d ) >> 1 ) \qquad ( 4 )$$

To calculate the distance, an inverse function can be used, such as that shown in Equation 5.

$$d = {K}_{EC}^{- 1} ( \frac{{I}_{RC} \cdot {K}_{RC}}{{I}_{O} \cdot K} ) \qquad ( 5 )$$

Equation 6 shows the relationship between the distance d and the emitting coil current. As the function K_{EC} decreases when d increases, the larger the distance d, the lower the value of K_{EC} and the larger I_{EC}.

$${I}_{EC} = {I}_{RC} \cdot {K}_{RC} \cdot \frac{1}{{K}_{EC} ( d )} \qquad ( 6 )$$

In addition, the SNR is independent of the distance d as the input magnetic field amplitude is defined by the reference coil 512. Equation 7 shows an example expression for this parameter. As noted, it does not depend on the distance.

$$S N R = \frac{{B}_{REF}}{{B}_{N}} = \frac{{K}_{RC} \cdot {I}_{RC}}{{B}_{N}} \qquad ( 7 )$$

While example embodiments of the disclosure are shown and described in conjunction with a CAPS sensor, it is understood that embodiments of the disclosure are applicable to any sensor functionality that can be generalized to a function ƒ that depends on a variable (x in this case) that is to be measured.

It is understood that any suitable magnetic field sensing element, such as Hall and MR elements can be used. While a voltage output from a sensing element may be designated as V_{TMR} indicated a TMR sensing element for an example embodiment, a wide range of sensing element types can be used.

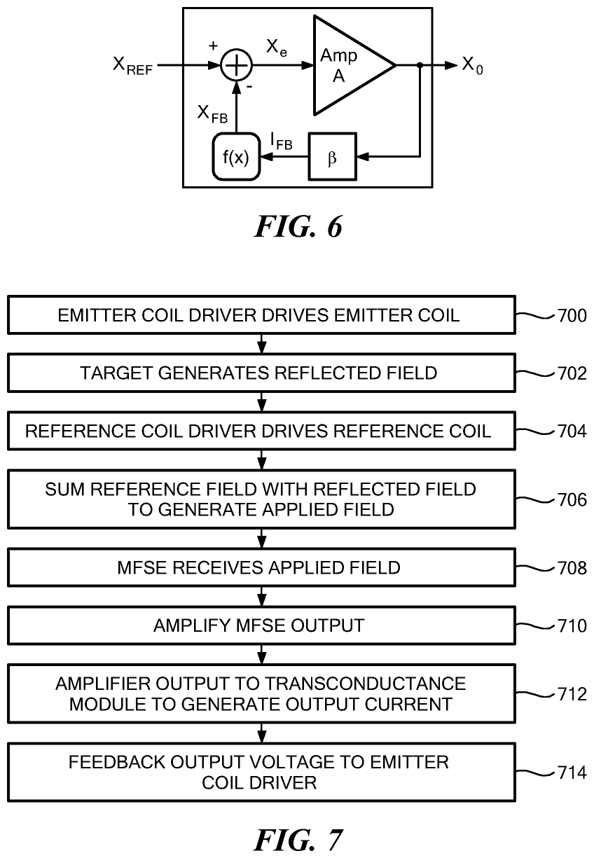

FIG. 6 shows a function ƒ(x) for the ratio between the current IFB to be managed and a variable X_{FB} used to feedback a closed loop architecture in accordance with Equation 8. It is understood that the variable X; can comprise a voltage, current, magnetic field, and the like

$$\frac{{X}_{FB}}{{I}_{FB}} = f ( x ) \qquad ( 8 )$$

Equation 9 shows the ratio between the reference X_{REF} and the output of the closed loop amplifier X₀.

$$\frac{{X}_{0}}{{X}_{REF}} {\overbrace{=}}^{A \cdot f ( x ) \cdot β >> 1} \frac{1}{f ( x ) \cdot β} \qquad ( 9 )$$

Equation 10 shows that the value of IFB can be defined by the reference X_{REF} and the function ƒ(x) that depends on the variable to measured x. Then, given a value of X_{REF}, the larger ƒ(x) the shorter the feedback current IFB and vice versa.

$${I}_{FB} = \frac{{X}_{REF}}{f ( x )} \qquad ( 10 )$$

The Equation 11 shows how the variable to be calculated x can be obtained.

$$x = {f}^{- 1} ( \frac{{X}_{FEF}}{{X}_{0} \cdot β} ) \qquad ( 11 )$$

The SNR is presented below in the Equation 12.

$$S N R = \frac{{X}_{REF}}{{X}_{N}} = \frac{f ( x ) \cdot {I}_{FC}}{{X}_{N}} \qquad ( 12 )$$

FIG. 7 shows an example sequence of steps for closed loop CAPS having emitter coil current that corresponds to a distance (d) between a die/sensing element and a conductive target. In step 700, an emitting coil driver generates an emitter current signal to an emitter coil. In step 702, a target generates a reflected field B_{R} in response to the field from the emitter coil. In step 704, a reference coil driver generates a reference current signal to a reference coil which generate a reference field B_{REF}, which in step 706, can be summed with the reflected field to generate field Be applied to a magnetic field sensing element in step 708. In step 710, The output of the MFSE is amplified to generate an output voltage for a transconductance module that generates an output current in step 712. In step 714, the output voltage is fed back to the emitter coil driver to form a closed loop feedback path with the emitter coil.

Example embodiments of the disclosure provide closed loop sensors that allow measurement of the distance (d) between a die and a conductive target instead. A magnetic field generates eddy currents in the target that reflects a magnetic field back to the die. A reflected magnetic field (B_{R}) is detected by magnetic field sensing elements with a certain sensitivity S_{T}, and then amplified. An emitting coil and the target are in the feedback loop to control a current to the emitting coil based on a distance to the target. With this arrangement, lower current levels can be used for closer targets.

Example CAPS implementations are shown and described in U.S. Pat. Nos. 10,996,289; 10,917,092; 11,624,791, each of which is incorporated herein by reference.

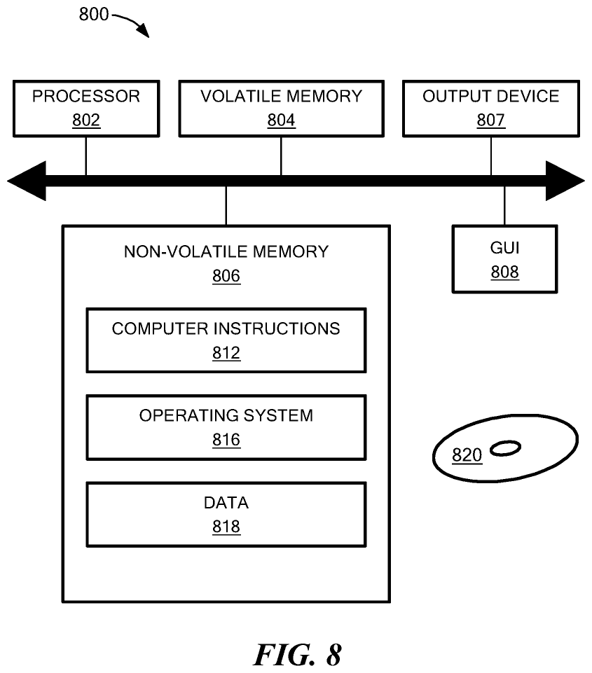

FIG. 8 shows an exemplary computer 800 that can perform at least part of the processing described herein. For example, the computer 800 can perform processing to control the emitter current. The computer 800 includes a processor 802, a volatile memory 804, a non-volatile memory 806 (e.g., hard disk), an output device 807 and a graphical user interface (GUI) 808 (e.g., a mouse, a keyboard, a display, for example). The non-volatile memory 806 stores computer instructions 812, an operating system 816 and data 818. In one example, the computer instructions 812 are executed by the processor 802 out of volatile memory 804. In one embodiment, an article 820 comprises non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., RAM/ROM, CD-ROM, hard disk, or magnetic diskette) that is readable by a general or special purpose programmable computer for configuring and operating the computer when the storage medium or device is read by the computer.

Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as special purpose logic circuitry (e.g., an FPGA (field programmable gate array), a general purpose graphical processing units (GPGPU), and/or an ASIC (application-specific integrated circuit)).

Various embodiments of the concepts, systems, devices, structures, and techniques sought to be protected are described above with reference to the related drawings. Alternative embodiments can be devised without departing from the scope of the concepts, systems, devices, structures, and techniques described. For example, while reference is made above to use of magnetoresistance elements, other types of magnetic field sensing elements may be used within the scope of the present disclosure. Furthermore, implementations of the described techniques may include hardware, a method or process, or computer software on a computer-accessible medium. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

It is noted that various connections and positional relationships (e.g., over, below, adjacent, etc.) may be used to describe elements in the description and drawing. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

Additionally, the term “exemplary” means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e., one, two, three, four, etc. The term “plurality” indicates any integer number greater than one. The term “connection” can include an indirect “connection” and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims. All publications and references cited in this patent are expressly incorporated by reference in their entirety.

What is claimed is:

1. A magnetic field sensor, comprising:
an emitter coil drive circuit for outputting an emitter current to an emitter coil for generating an emitter field;
a reference coil drive circuit for outputting a reference current to a reference coil for generating a reference field;
a combiner to combine a reflected field generated by a target in response to the emitter field and the reference field and output an applied field;
a magnetic field sensing element to receive the applied field and generate an electric signal;
an amplifier to amplify the electric signal, wherein an output of the amplifier is coupled to the emitter coil drive circuit;
a transconductance module to generate an output current from the electric signal;
wherein the sensor comprises a closed loop configuration with a feedback path that includes the emitter coil drive circuit and the emitter coil and is configured to modify an amplitude of the emitter current signal based on a distance from the target to the magnetic field sensing element.

2. The sensor according to claim 1, wherein the applied field comprises a signal at carrier frequency.

3. The sensor according to claim 1, wherein the output signal from the magnetic field sensing element is demodulated to a baseband frequency and input to the amplifier.

4. The sensor according to claim 1, wherein the distance d is determined as
$$d = {K}_{EC}^{- 1} ( \frac{{I}_{RC} \cdot {K}_{RC}}{{I}_{O} \cdot K} )$$
where Io is the output current from the transconductance module, I_{RC} is the reference current

| | | |
|---|---|---|
| K_{EC}(d) | [G/A] | Ratio between the emitting coil current IEC and |
| | | the reflected magnetic field BR |
| K_{FC}, K_{RC} | [G/A] | Feedback and reference coils sensitivity |
| K | [A/A] | Transconductances ratio. |

5. The sensor according to claim 1, wherein the emitter current is determined as:
$${I}_{EC} = {I}_{RC} \cdot {K}_{RC} \cdot \frac{1}{{K}_{EC} ( d )}$$
where I_{RC} is the reference current, and

| | | |
|---|---|---|
| K_{EC}(d) | [G/A] | Ratio between the emitting coil current I_{EC} and |
| | | the reflected magnetic field BR |
| K_{FC}, K_{RC} | [G/A] | Feedback and reference coils sensitivity. |

6. The sensor according to claim 1, wherein the magnetic field sensing element comprises a magnetoresistance (MR) element.

7. The sensor according to claim 1, wherein the magnetic field sensing element comprises a Hall element.

8. A method, comprising:
outputting an emitter current to an emitter coil for generating an emitter field;
outputting a reference current to a reference coil for generating a reference field;
combining a reflected field generated by a target in response to the emitter field and the reference field and output an applied field;
receiving the applied field and generating an electric signal by a magnetic field sensing element in a magnetic field sensor;
amplifying the electric signal with an amplifier, wherein an output of the amplifier is coupled to an emitter coil drive circuit for generating the emitter current; and
generating an output current from the electric signal;
wherein the sensor comprises a closed loop configuration with a feedback path that includes the emitter coil drive circuit and the emitter coil and is configured to modify an amplitude of the emitter current signal based on a distance from the target to the magnetic field sensing element.

9. The method according to claim 8, wherein the applied field comprises a signal at carrier frequency.

10. The method according to claim 8, wherein the output signal from the magnetic field sensing element is demodulated to a baseband frequency and input to the amplifier.

11. The method according to claim 1, wherein the distance d is determined as
$$d = {K}_{EC}^{- 1} ( \frac{{I}_{RC} \cdot {K}_{RC}}{{I}_{O} \cdot K} )$$
where Io is the output current from the transconductance module, I_{RC} is the reference current,

| | | |
|---|---|---|
| K_{EC}(d) | [G/A] | Ratio between the emitting coil current IEC and |
| | | the reflected magnetic field BR |
| K_{FC}, K_{RC} | [G/A] | Feedback and reference coils sensitivity |
| K | [A/A] | Transconductances ratio. |

12. The method according to claim 1, wherein the emitter current is determined as:
$${I}_{EC} = {I}_{RC} \cdot {K}_{RC} \cdot \frac{1}{{K}_{EC} ( d )}$$
where I_{RC} is the reference current, and

| | | |
|---|---|---|
| K_{EC}(d) | [G/A] | Ratio between the emitting coil current I_{EC} and |
| | | the reflected magnetic field BR |
| K_{FC}, K_{RC} | [G/A] | Feedback and reference coils sensitivity. |

13. The method according to claim 8, wherein the magnetic field sensing element comprises a magnetoresistance (MR) element.

14. The method according to claim 1, wherein the magnetic field sensing element comprises a Hall element.

15. A magnetic field sensor, comprising:
an emitter coil drive circuit for outputting an emitter current to an emitter coil for generating an emitter field;
a reference coil drive circuit for outputting a reference current to a reference coil for generating a reference field;
a combiner to combine a reflected field generated by a target in response to the emitter field and the reference field and output an applied field;
a magnetic field sensing element to receive the applied field and generate an electric signal;
an amplifier to amplify the electric signal, wherein an output of the amplifier is coupled to the emitter coil drive circuit;
a transconductance module to generate an output current from the electric signal; and
a means for providing a closed loop feedback.
